(19) United States
(12) Patent Application Publication
(10) Pub. No.: US 2010/0303258 A1
(43) Pub. Date: Dec. 2, 2010

(54) PORTABLE MEDIA DELIVERY SYSTEM WITH A MEDIA SERVER AND HIGHLY PORTABLE MEDIA CLIENT DEVICES

(76) Inventor: Yang Pan, Singapore (SG)

Correspondence Address: Yang Pan;Intellectual Power Pte Ltd, No. 14 Robinson Road #06-01,, Far East Finance Building, Singapore, 048545, SG

(21) Appl. No.: 12/852,486

(22) Filed: Aug. 8, 2010

Related U.S. Application Data
(63) Continuation-in-part of application No. 12/172,270, filed on Jul. 14, 2008.

(51) Int. Cl. H03G 3/00; H03M 11/00; G06F 17/00

(52) U.S. Cl. 381/104; 341/20; 700/90

(57) ABSTRACT

A media delivery system comprises a portable media server and a client device. The client device may be a button-less audio player. Sensors are used to generate control signals through a user's interaction. Sensors may be located in earphones to increase or to decrease sound volume. Applications based on touch, pressure, temperature, thermal and motion sensors are disclosed.

### CROSS-REFERENCE TO RELATED APPLICATIONS

The present disclosure is a Continuation-in-Part of the prior application Ser. No. 12/172,270 filed on Jul. 14, 2008.

### BACKGROUND

1. Field of Invention

This invention relates to a media delivery system, specifically to methods of controlling operations of portable media players.

2. Description of Prior Art

A portable media player stores media assets such as songs and video clips, which can be played on the device. Examples of media players are the iPod from Apple Inc. of Cupertino, Calif., the Zen from Creative Technology Ltd, Singapore and the Zune from Microsoft Inc of Redmond, Wash. A media player acquires typically its media assets from a computer with media management applications, such as the iTunes software from Apple. The portable media players have gained popularity because of its capability to store large number of media assets in a device, which can be put into a user's pocket when he or she is moving around. The large number of media assets are organized in a way of automatic hierarchical categorization by metadata as disclosed in U.S. Pat. No. 6,928,433 to Goodman and Egan. Portable media players with wireless communication capabilities have been disclosed by Fadell, et al in US Patent Publication 2008/0125031.

Despite of the gained popularity of the portable media players, there are two conflicting requirements for the device. On one hand, it is becoming popular to integrate multiple functions into a single handheld device. For example, an iPhone from Apple can be used as a mobile phone, as an internet connecting device, and as a media player. More functions in a single device typically demand a bulky battery to provide a reasonably long operation lifetime. On the other hand, the compactness of the device is a critical requirement for some users, in particular, when it is used for wearing to have a physical exercise. As a result of the conflicting requirements, different types of portable media players have been provided in the market for different applications. It is, however, not always convenient for a user to maintain multiple portable media products for different occasions when the same media database in a personal computer is maintained.

In US Patent Publication 2008/0013274, Jobs et al disclosed an art to have an improved portable media device. The device is small by eliminating the display screen. It was recognized by the inventors that a user would encounter difficulties to use a display screen integrated with a reduced size device. The compactness of the device, however, has not been fully achieved because of the presence of the visible user input devices.

Therefore, what is desired is a portable media device with even smaller size that is suitable for a user to carry to have a physical exercise. What is further desired is a portable media delivery system including a portable media server and highly portable client devices. The server may be a portable device such as the iPhone from Apple. The highly portable media client devices may be a stripped-down version of media device consisting of much reduced number of components. The client device is ideally a plug and play apparatus for the server. The client device receives selected media assets from the server.

Accordingly, it is a purpose of the present invention to provide a portable media delivery system including a portable media server and portable media client devices.

It is a further purpose of the present invention to provide an extremely compact audio player. The audio player does not require a display screen and a visible user input device to be functional.

It is yet a further purpose of the present invention to provide methods of using various sensors in earphones to control the sound volume of an audio player.

### SUMMARY OF THE INVENTION

A portable media delivery system comprises a portable media server and at least one highly portable media client device. An audio player is used in an exemplary manner to illustrate the present inventive concept. An audio player as an exemplary case of the client device may be a stripped-down version of a media player. The display screen and the user input devices are eliminated to further reduce the size of the device. The selected media assets transferred through the wired or the wireless connection from the portable media server are stored in a storage device such as a cache of the audio player.

The present invention as the Continuation-in-Part of the prior application further discloses methods for adjusting sound volume by utilizing of various types of sensors.

In accordance with one embodiment of the present invention, each of two earphones includes a touch sensor. One is used to increase the sound volume and another is to reduce the sound volume.

In accordance with another embodiment of the present invention, each of two earphones includes a pressure sensor. One is used to increase the sound volume and another is to reduce the sound volume.

In accordance with yet another embodiment of the present invention, each of two earphones includes a temperature sensor. One is used to increase the sound volume and another is to reduce the sound volume.

In accordance with still another embodiment of the present invention, each of two earphones includes a thermal sensor. The thermal sensors may be heated to a predetermined temperature above its ambient temperature by using a control circuitry. A user touches a sensor generates a signal to a control device. One of the sensors is used to increase the sound volume and another to decrease the sound volume.

In accordance with still another embodiment of the present invention, each of two earphones includes a combination of different types of sensors. One is used to increase the sound volume and another is to reduce the sound volume.

### BRIEF DESCRIPTION OF THE DRAWINGS

For a more complete understanding of the present invention and its various embodiments, and the advantages thereof, reference is now made to the following description taken in conjunction with the accompanying drawings, in which:

FIG. 1 is a schematic diagram that each of two earphones includes a sensor for controlling operations of a media player;

FIG. 2 is a flow diagram illustrating the method of using sensors in earphones to control the operations of the media player;

FIG. 3 is a flow diagram illustrating the method of using sensors in earphone to adjust sound volume of the media player;

FIG. 4 is a schematic diagram that each of two earphones includes a motion sensor for controlling sound volume of the media player;

FIG. 5 is a schematic diagram that each of two earphones includes a touch sensor for controlling sound volume of the media player;

FIG. 6 is a schematic diagram that each of two earphones includes a pressure sensor for controlling sound volume of the media player;

FIG. 7 is a schematic diagram that each of two earphones includes a temperature sensor for controlling sound volume of the media player;

FIG. 8 is a schematic diagram that each of two earphones includes a thermal sensor for controlling sound volume of the media player;

FIG. 9 is a schematic diagram that each of two earphones includes a combination of different types of sensors for controlling sound volume of the media player;

FIG. 10 is a schematic diagram illustrating that each of two earphones may be associated with a touch identifiable symbol.

### DETAILED DESCRIPTION

References will now be made in detail to a few embodiments of the invention, examples of which are illustrated in the accompanying drawings. While the invention will be described in conjunction with the particular embodiments, it will be understood that it is not intended to limit the invention to the described embodiments. To the contrary, it is intended to cover alternatives, modifications, and equivalents as may be included within the spirit and scope of invention as defined by the appended claims.

A portable media delivery system comprises a portable media server and at least one highly portable media client device. An audio player is used in an exemplary manner to illustrate the present inventive concept. According to one embodiment of the present invention, the server and the client device may be two independent devices. According to one aspect of the invention, the server and the client device are connectable through a conventional wired connection such as through a Universal Serial Bus (USB) type of connection. According to another aspect of the present invention, the portable media server and the client devices are connected through a wireless communication means. In such an implementation, multiple client devices may be connected to the server concurrently.

An audio player as an exemplary case of the client device may be a stripped-down version of a media player. The display screen and the user input devices are eliminated to further reduce the size of the device. The selected media assets transferred through the wired or the wireless connection from the portable media server are stored in a storage device such as a cache of the audio player.

According to another embodiment of the present invention, the audio player as an exemplary client device is a subsystem of the portable media server. The audio player may be detachable from the server. In such an implementation, the audio player as a part of the media server is connected to the host through a wired connection such as through the USB type of connector. The audio player, comprising a processor, a cache, a CODEC and a battery, is an integrated part of the portable media server. The cache stores selected media assets from the media file system of the server. When detached, the audio player is operated independently while the media server ceases to be functional.

The present invention discloses highly portable media player controlled by various sensors. The media player may be a button-less electronic device. The media player may be a sub-system of a media delivery system as disclosed in the prior application. The media player may also be a standalone media player.

Although a portable media player is used in exemplary manner to illustrate the present invention, the inventive concept can be applied to any electronic device which uses earphones.

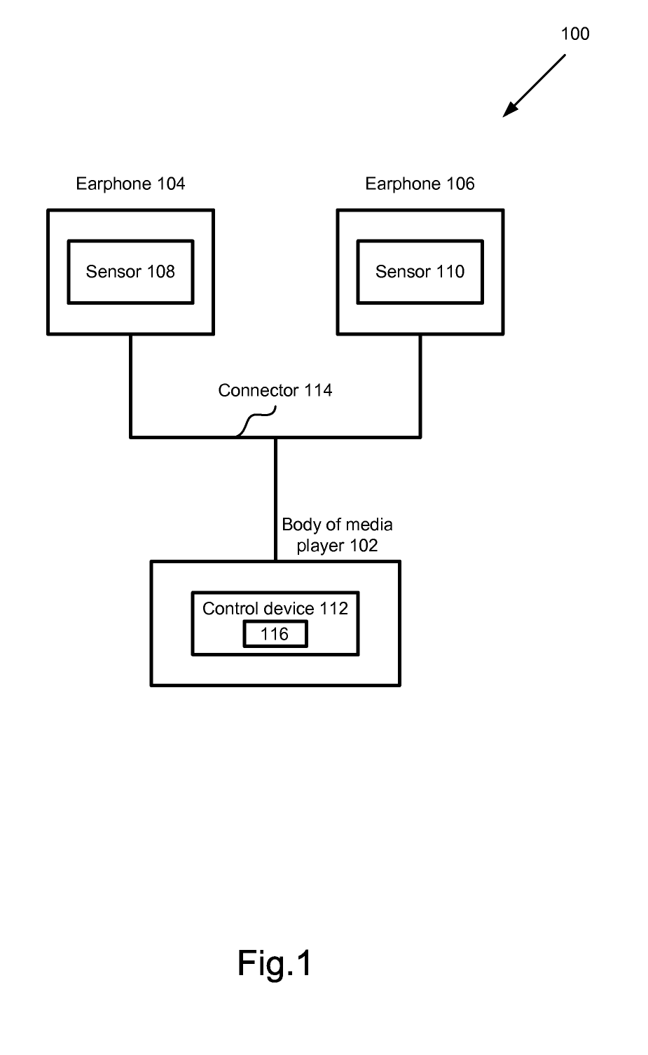

FIG. 1 shows a schematic diagram of a portable media player 100. The player 100 includes a body of the media player 102 comprising sub-systems such as for example, a processor, a file storage system, an audio signal processing unit and a battery. The player 100 also includes a first earphone 104 and a second earphone 106. The first earphone 104 includes a first sensor 108. The second earphone 106 includes a second sensor 110. The sensors may also include local data processing units in the earphones 106 and 108. The body of the media player 102 may further include a control device 112 for receiving the signals from the sensor 108 and 110 and for generating control signals based on the received signal. The earphones are connected to the body of the media player 102 through a connector 114. The connector 114 may be a wired connection. The connector 114 may also be a wireless connection. In an exemplary case, the earphones 104 and 106 may be connected to the body 102 through a Bluetooth type of connection.

The sensors 108 and 110 may be installed inside the earphone. The sensors 108 and 110 may also be installed on a surface of the earphones. The user's interaction through his fingers may generate a signal. The control device 112 receives the signal and generates a control signal accordingly.

According to another aspect of the present invention, the control device 112 may further include a switch 116. The switch 116 is used to enable the control mechanism by using the sensors. The switch 116 may be a motion sensor according to one implementation. The user may switch on the sensors by repeatedly weaving the body of the media player.

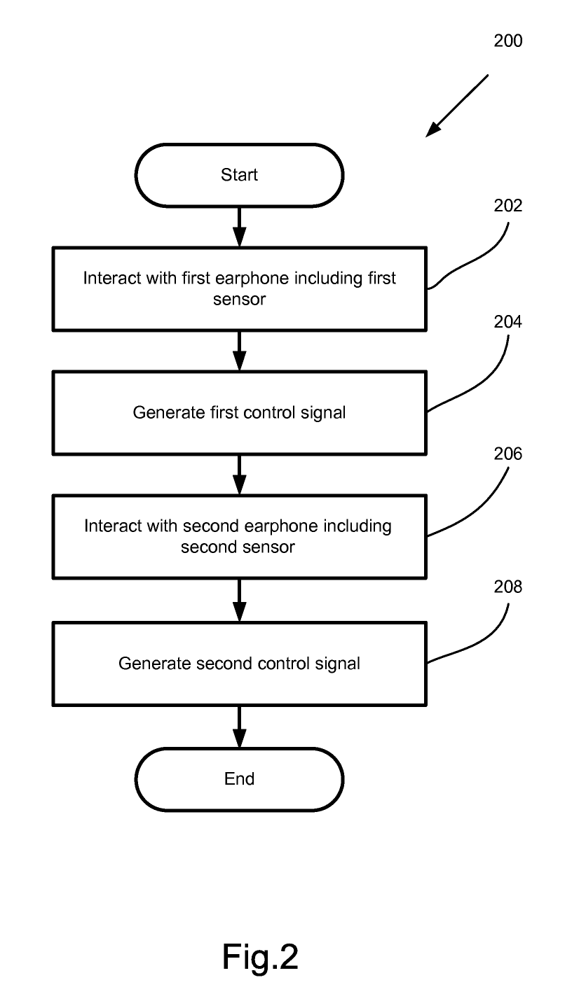

FIG. 2 is a flow diagram illustrating the method of using sensors in earphones to control the operations of the media player. Process 200 starts with step 202 that the user interacts with the first earphone 104 including the first sensor 108. A signal is generated by the first sensor 108 and is sent to the control device 112. The control device 112 generates the first control signal in step 204. The operation of the media player 100 is changed according to the control signal. In step 206, the user interacts with the second earphone 106 including the second sensor 110. A signal is generated by the second sensor 110 and is sent to the control device 112. The control device 112 generates the second control signal in step 208. The operation of the media player 100 is changed according to the second control signal.

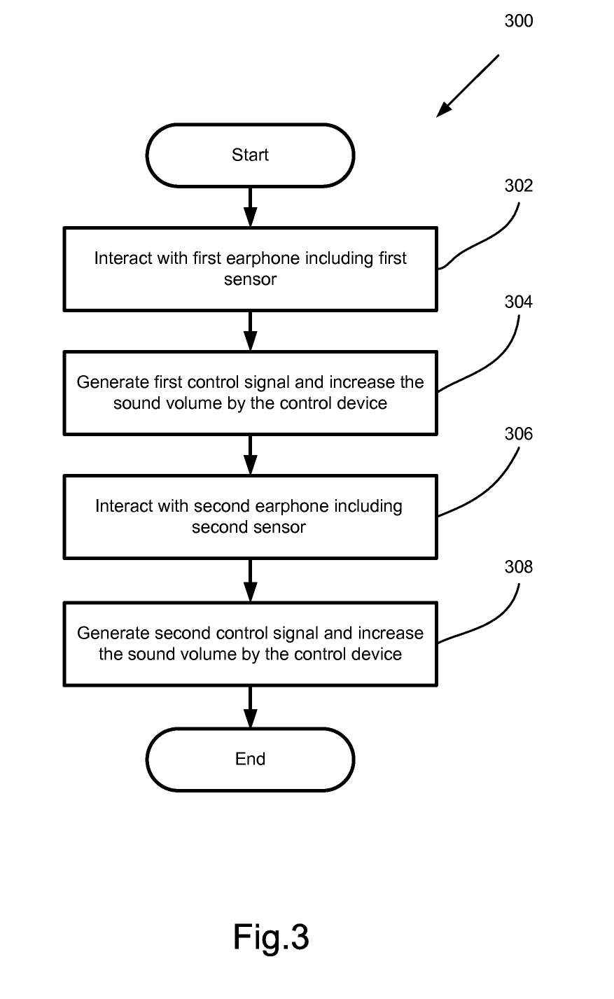

FIG. 3 is a flow diagram illustrating the method of using sensors in earphone to adjust sound volume of the media player. Process 300 starts with step 302 that the user interacts with the first earphone 104 including the first sensor 108. A signal is generated by the first sensor 108 and is sent to the control device 112. The control device 112 generates the first control signal in step 304 and the sound volume of the media player 100 is increased according to the control signal. In step 306, the user interacts with the second earphone 106 including the second sensor 110. A signal is generated by the second sensor 110 and is sent to the control device 112. The control device 112 generates the second control signal in step 308 and the sound volume of the media player 100 is decreased accordingly. It should be noted that the control device 112 provides a control mechanism to generate a control signal only if the received signal is above a predetermined threshold.

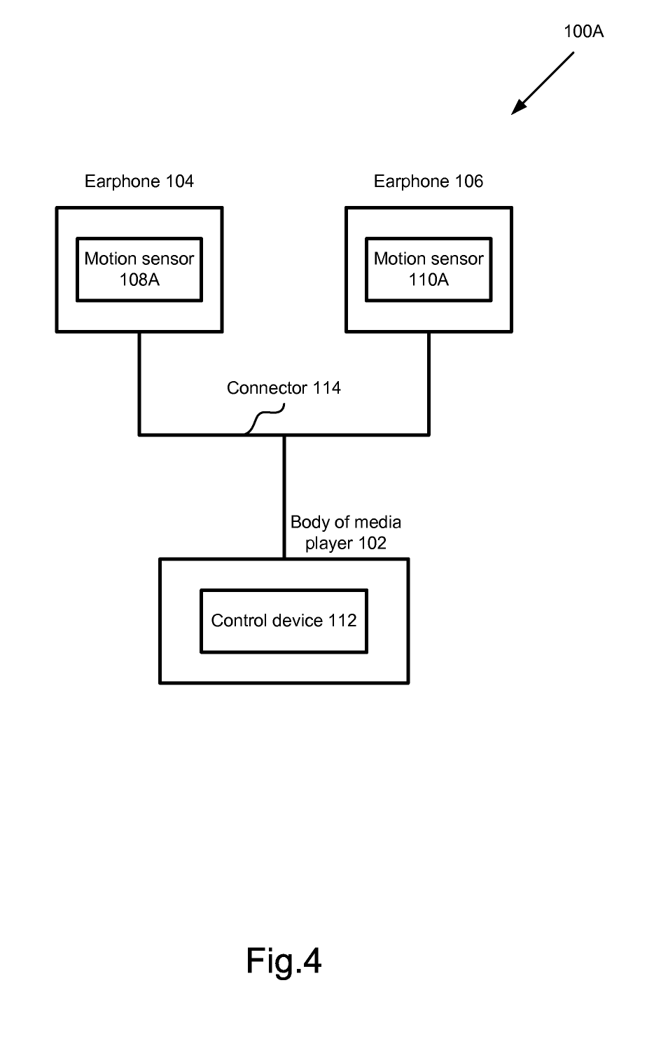

FIG. 4 is a schematic diagram that each of two earphones includes a motion sensor for controlling sound volume of the media player. Motion sensors 108A and 110A are included in the earphones 104 and 106, respectively. The user may weave or tap the first sensor 108A. The signal generated by the motion sensor 108A is sent to the control device 112 and the sound volume of the media player 100 is increased. The user may also weave or tap the second earphone. The signal generated by the motion sensor 110A is sent to the control device 112 and the sound volume of the media player 100 is decreased. The motion sensor may be an accelerometer. The motion sensor may also be a gyroscope.

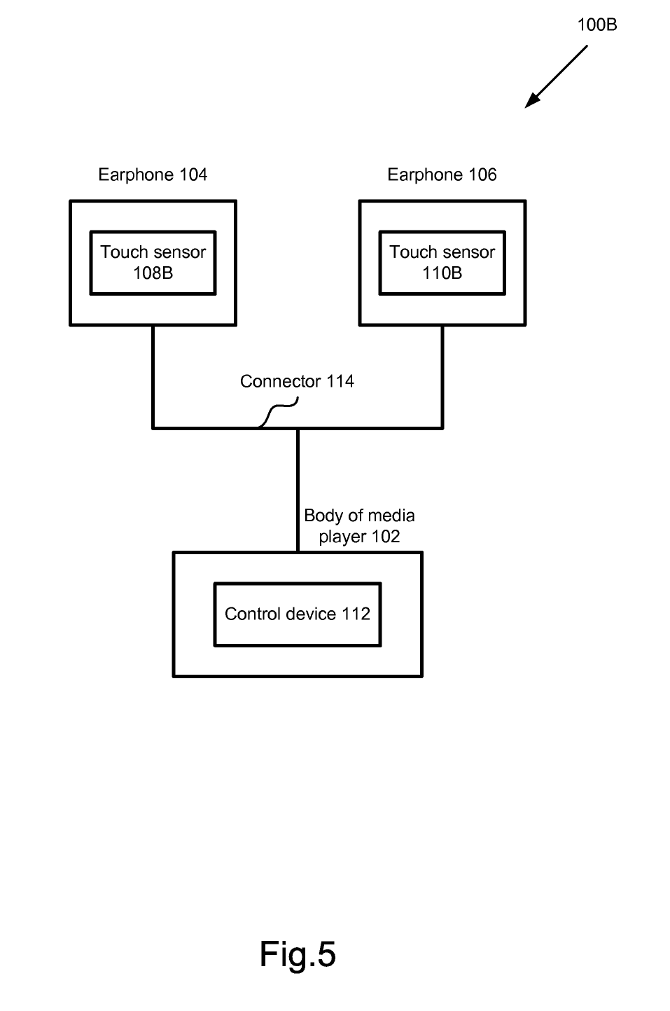

FIG. 5 is a schematic diagram that each of two earphones includes a touch sensor for controlling sound volume of the media player. Touch sensors 108B and 110B are included in the earphones 104 and 106, respectively. The touch sensors may be a part of surfaces of the earphones 104 and 106. Touch screens have been used widely in today's electronic devices. The present invention discloses an innovative method to use the touch sensor or touch screen in an exemplary case as a part of the surfaces of the earphones. The user may use his finger to touch the surface of one of the earphones. The touch sensor generates a signal accordingly. The signal generated by the touch sensor 108B is sent to the control device 112 and the sound volume of the media player 100 is increased. The user may also touch the second earphone 106. The signal generated by the touch sensor 110B is sent to the control device 112 and the sound volume of the media player 100 is decreased. In an exemplary case, the user may use his right-hand finger (s) to touch one of the earphones and use his left-hand finger (s) to touch another earphone. The frequency of touching may be recorded as a signal. The higher of the touching frequency, the stronger the signal generate by the control device 112 to increase or to decrease the sound volume.

In another implementation, a single touch sensor may be used to adjust the sound volume. The user may touch the surface along one direction to increase the sound volume. The user may also touch the surface along another direction to decrease the sound volume.

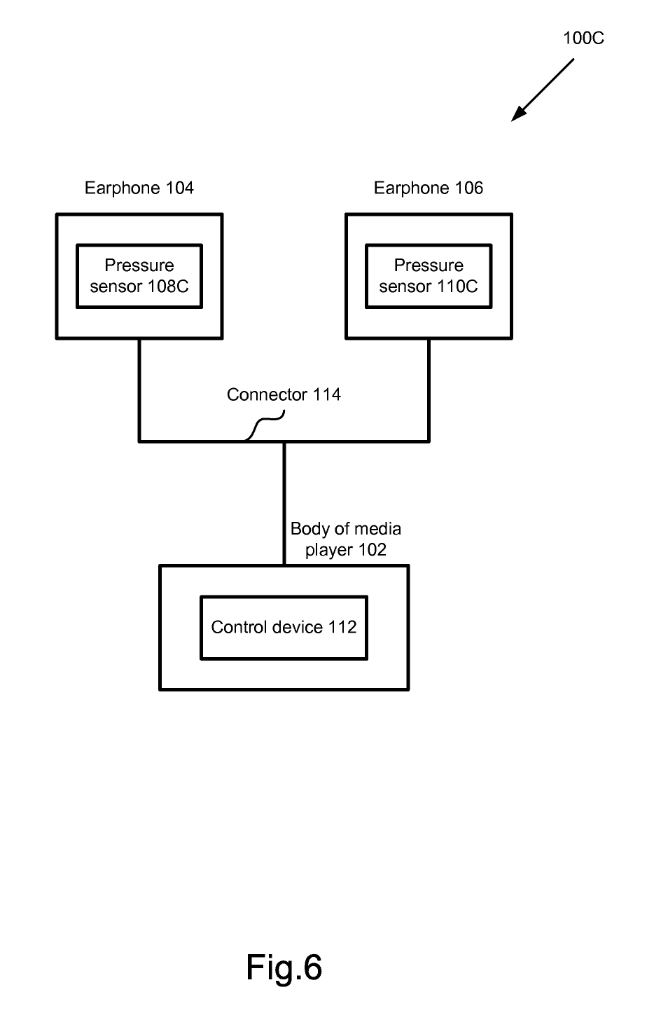

FIG. 6 is a schematic diagram that each of two earphones includes a pressure sensor for controlling sound volume of the media player. Pressure sensors 108C and 110C are included in the earphones 104 and 106, respectively. The pressure sensors may be installed as a part of surfaces of the earphones 104 and 106. Pressure sensors have been used widely in today's electronic devices. The present invention discloses an innovative method to use the pressure sensors in an exemplary case as a part of the surfaces of the earphones. The pressure sensors may be installed as a part of the surface structure in an invisible manner to the user. The user may use his finger to apply a pressure to the surface of one of the earphones. The pressure sensor generates a signal accordingly. The signal generated by the pressure sensor 108C is sent to the control device 112 and the sound volume of the media player 100 is increased. The user may also apply a pressure to the second earphone 106. The signal generated by the pressure sensor 110C is sent to the control device 112 and the sound volume of the media player 100 is decreased. In an exemplary case, the user may use his right-hand finger (s) to tap one of the earphones and may use his left-hand finger (s) to tap another earphone. The frequency of tapping may be recorded as a signal. The higher of the tapping frequency, the stronger the signal generate by the control device 112 to increase or to decrease the sound volume.

In another implementation, a single pressure sensor may be used to adjust the sound volume. The user may apply the pressure along one direction to increase the sound volume. The user may apply the pressure along another direction to decrease the sound volume.

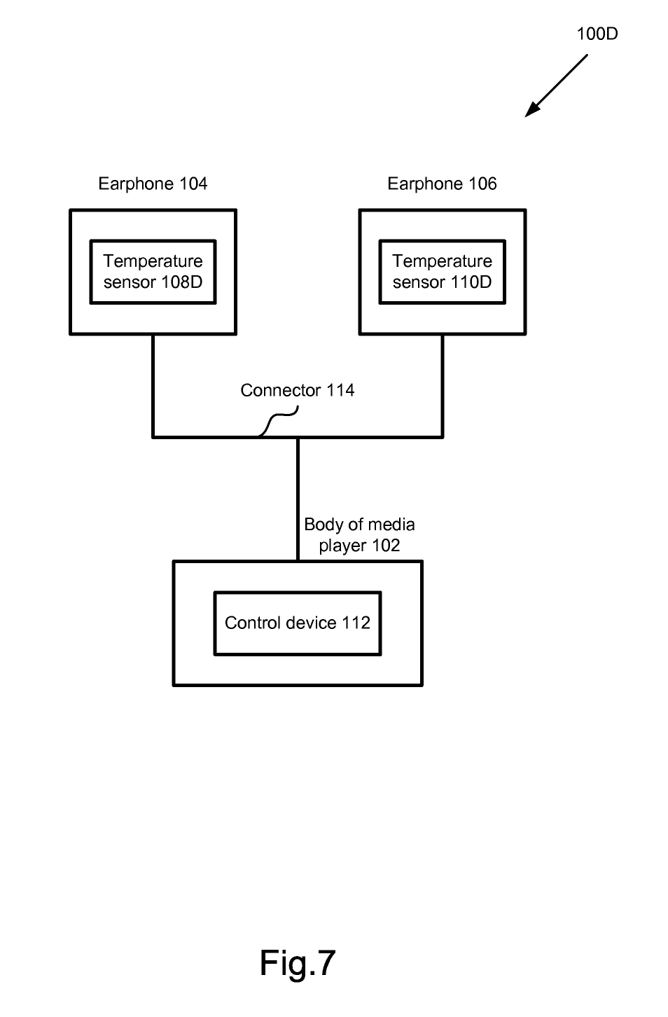

FIG. 7 is a schematic diagram that each of two earphones includes a temperature sensor for controlling sound volume of the media player. Temperature sensors 108D and 110D are included in the earphones 104 and 106, respectively. The temperature sensors may be installed as a part of surfaces of the earphones 104 and 106. Temperature sensors have been used widely in today's electronic devices. The present invention discloses an innovative method to use the temperature sensors in an exemplary case as a part of the surfaces of the earphones. The user may use his finger to touch the surface of one of the earphones. The temperature sensor generates a signal accordingly. The signal generated by the temperature sensor 108D is sent to the control device 112 and the sound volume of the media player 100 is increased. The user may touch the second earphone 106. The signal generated by the temperature sensor 110D is sent to the control device 112 and the sound volume of the media player 100 is decreased.

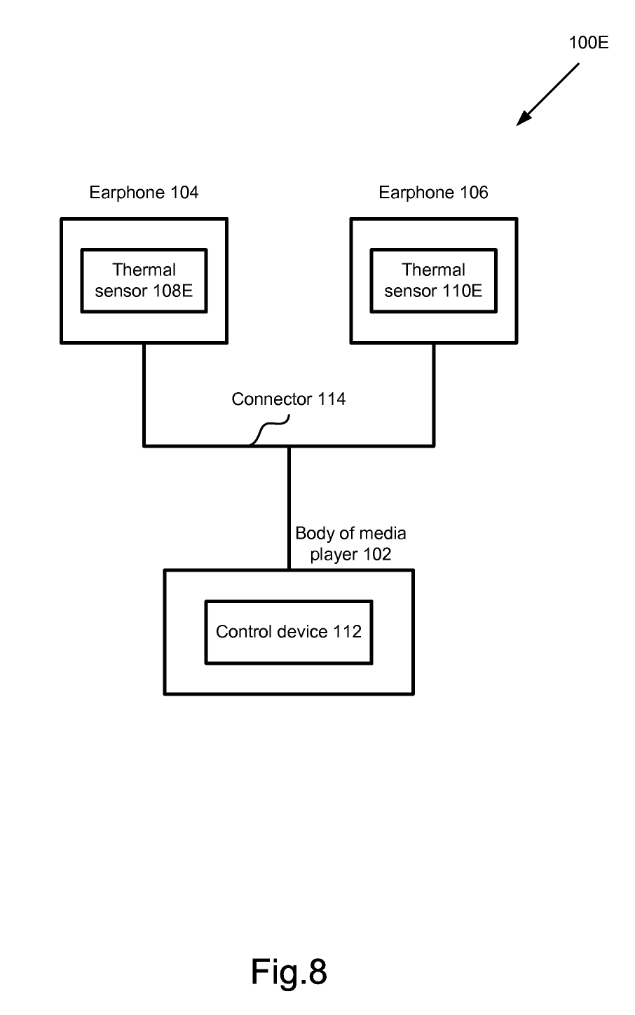

FIG. 8 is a schematic diagram that each of two earphones includes a thermal sensor for controlling sound volume of the media player. Thermal sensors 108E and 110E are included in the earphones 104 and 106, respectively.

The thermal sensors have been used in prior art to measure flow velocity as published by Y. Pan et al in Electron. Lett. Vol 24, pp 542-543, 1988. A thermal sensor may be a MEMS based silicon sensor. The thermal sensor may include a heating element, a temperature sensor and a control circuitry. The heating element which may be a resistor in an exemplary case is used to heat a mass to a temperature above its ambient. The control circuitry is used to control the temperature different between the mass and the ambient as a constant. For example if the ambient temperature is increased, the control circuitry deliveries more heating power to maintain the temperature difference as the constant. If the heat dissipation path is blocked by a finger of the user, the less heating power is required to maintain the temperature difference. The heating power, measured by the product of voltage across the heating element (resistor) and the current passing the element, is an indication if the heat dissipation path is blocked by an object such as the user's finger.

The thermal sensors may be installed as a part of surfaces of the earphones 104 and 106. The present invention discloses an innovative method to use the thermal sensors as a part of the surfaces of the earphones to receive the user's inputs. The user may use his finger to touch the surface of one of the earphones. The thermal sensor generates a signal accordingly. The signal generated by the thermal sensor 108E is sent to the control device 112 and the sound volume of the media player 100 is increased. The user may touch the second earphone 106. The signal generated by the thermal sensor 110E is sent to the control device 112 and the sound volume of the media player 100 is decreased.

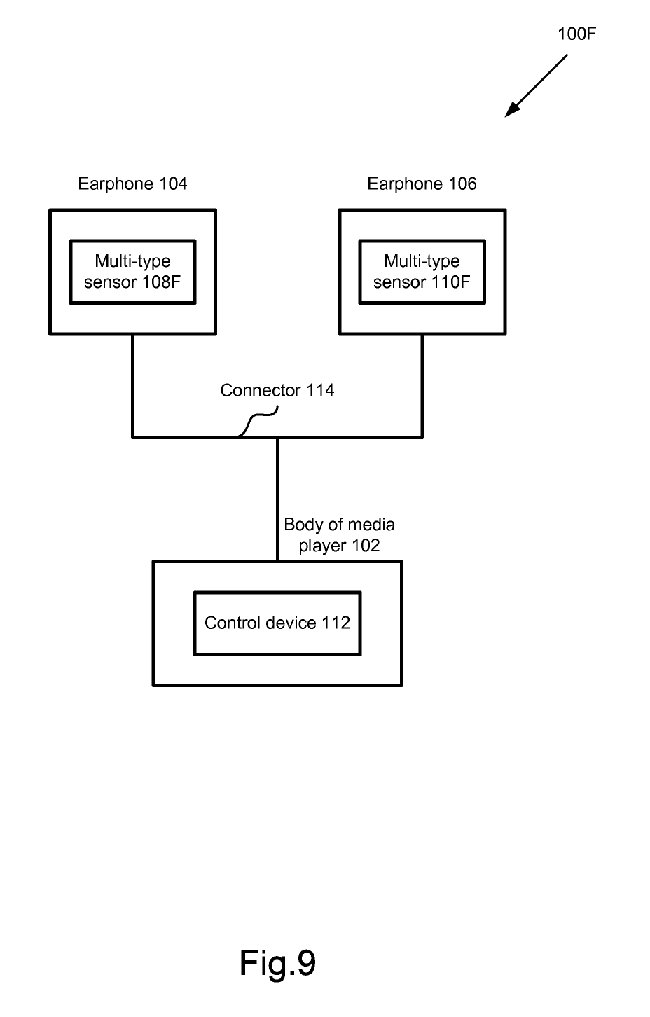

FIG. 9 is a schematic diagram that each of two earphones includes a combination of different types of sensors for controlling sound volume of the media player. The sensor 108F and 110F may include more than one type of sensors. For example, a motion sensor may be combined with a touch sensor to increase reliability of the operations. A pressure sensor may used in combination with a temperature sensor.

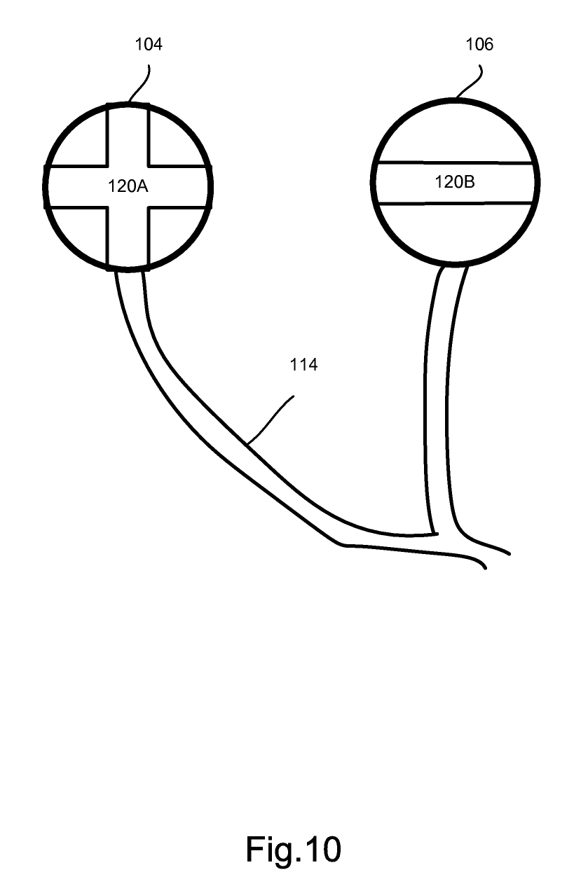

FIG. 10 is a schematic diagram illustrating that each of two earphones 104 and 106 may be associated with a touch identifiable symbol. The touch identifiable symbol 120A or 120B may be a part of the surface of earphones 104 and 106. When the user is using the media player, it is desirable that the user identifies the functionalities of the earphone by touching the earphones only. In another implementation, the touch identifiable symbols may also be attached to the part of the connectors 114 close to the earphones 104 and 106.

While the invention has been disclosed with respect to a limited number of embodiments, numerous modifications and variations will be appreciated by those skilled in the art. It is intended that all such variations and modifications fall with in the scope of the following claims:

1. A method of a user controlling operations of a handheld media player including a control device and a first and a second earphone, wherein the first earphone comprising first sensor and the second earphone comprising second sensor, the method comprising:
a. generating a first control signal after the user's interaction with the first sensor in the first earphone;
b. conducting a first control action;
c. generating a second control signal after the user's interaction with the second sensor in the second earphone; and
d. conducting a second control action.

2. The method as recited in claim 1, wherein said first control action comprising adjusting up the sound volume and said second control action comprising adjusting down the sound volume of said earphones.

3. The method as recited in claim 1, wherein said sensors comprising touch sensors located on a surface of said earphones that generate a signal when the user touches the surface of the earphones by using fingers.

4. The method as recited in claim 1, wherein said sensors comprising pressure sensors that generate a signal when the user applies pressure to the surface of the earphones by using fingers.

5. The method as recited in claim 1, wherein said sensors comprising temperature sensors that generate a signal when the user is in contact with the earphones.

6. The method as recited in claim 1, wherein said sensors comprising thermal sensors, being heated to a predetermined temperature elevation above an ambient temperature, wherein said thermal sensors generate a signal when the user's finger blocks a heat transfer path from the sensors to the ambient.

7. The method as recited in claim 1, wherein said sensors comprising motion sensors that generate a signal when the user weaving or taping the earphone.

8. The method as recited in claim 1, wherein said sensors comprising any combination of said touch, pressure, temperature, thermal and motion sensors.

9. The method as recited in claim 1, wherein said control device further comprising a switch for switching on or off the functionalities of said sensors, wherein said switch further comprising a motion sensor.

10. A button-less handheld media player comprising:
a. a body comprising a plurality of functional blocks for the media player;
b. a control device;
c. a first earphone including a first sensor;
d. a second earphone including a second sensor; and
e. a connector connecting the earphones and the body.

11. The media player as recited in claim 10, wherein said sensors comprising touch sensors located on a surface of said earphones that generate a signal when the user touches the surface of the earphones by using fingers.

12. The media player as recited in claim 10, wherein said sensors comprising pressure sensors that generate a signal when the user applies pressure to the surface of the earphones by using fingers.

13. The media player as recited in claim 10, wherein said sensors comprising temperature sensors that generate a signal when the user is in contact with the earphones.

14. The media player as recited in claim 10, wherein said sensors comprising thermal sensors, being heated to a predetermined temperature elevation above an ambient temperature, wherein said thermal sensors generate a signal when the user's finger blocks a heat transfer path from the sensors to the ambient.

15. The media player as recited in claim 10, wherein said sensors comprising any combination of touch, pressure, temperature, thermal and motion sensors.

16. The media player as recited in claim 10, wherein said first earphone and said second earphone comprising a touch identifiable symbols that differentiating their functionalities for generating the control signals.

17. The media player as recited in claim 10, wherein said control device further comprising a switch for switching on or off the functionalities of said sensors, wherein said switch further comprising a motion sensor.

18. A handheld electronic device comprising a means of generating a control signal through detecting a user's interaction with a pair of sensors located in its accessories including earphones.

19. The device as recited in claim 18, wherein said a pair of sensors generating a control signal when the user interacts with at least one of the sensors.

20. The device as recited in claim 18, wherein said sensors are selected from the following group:
a. touch sensors;
b. pressure sensors;
c. temperature sensors;
d. thermal sensors including a heating element, a control element and a temperature measuring element;
e. motion sensors; and
f. any combination of the above mentioned sensors.
